(19) United States
(12) Patent Application Publication
(10) Pub. No.: US 2020/0295268 A1
(43) Pub. Date: Sep. 17, 2020

(54) ORGANIC LIGHT-EMITTING MATERIAL, METHOD FOR THE PREPARATION THEREOF AND USE THEREOF

(71) Applicants: Shenzhen Chian Star Optoelectronics Technology Co., Ltd., Shenzhen (CN); Sun Yat-Sen University, Guangzhou (CN)

(72) Inventors: Xianjie Li, Shenzhen (CN); Yuanchun Wu, Shenzhen (CN); Poyen Lu, Shenzhen (CN); Tao Yu, Guangzhou (CN); Qiuyi Huang, Guangzhou (CN); Zongliang Xie, Guangzhou (CN); Depei Ou, Guangzhou (CN); Leyu Wang, Guangzhou (CN); Zhenguo Chi, Guangzhou (CN); Yi Zhang, Guangzhou (CN); Siwei Liu, Guangzhou (CN); Jiarui Xu, Guangzhou (CN)

(21) Appl. No.: 16/081,919

(22) PCT Filed: Jan. 9, 2018
(86) PCT No.: PCT/CN2018/072012

§ 371 Date: Sep. 3, 2018

(30) Foreign Application Priority Data
Dec. 6, 2017 (CN) 201711279756.4

(51) Int. Cl. H01L 51/00

(52) U.S. Cl. CPC H01L 51/0072; H01L 51/5072

(57) ABSTRACT

An organic light-emitting material, a method for the preparation thereof and use thereof are provided. The organic light-emitting material is a novel organic light-emitting material containing phosphine, has a high electron-transport property and a high fluorescence quantum efficiency, can be used as an emitting layer material and/or an electron transport layer material in an OLED element. Thus, an emitting layer and an electron transport layer in a traditional OLED element can be combined as one layer, thereby simplifying the structure and preparation process of the OLED element. Also, the organic light-emitting material has a specific response to oxygen, metal ions, etc., so that the organic light-emitting material can also be applied in the fields of chemo-biological detection, bio-imaging, anti-counterfeiting, etc. There are advantages of simple synthesis and purification, high yield, and adjustment of its luminous wavelength, luminous efficiency, etc. by introducing different functional groups.

### BACKGROUND OF THE INVENTION

### 1. Field of the Invention

The present disclosure relates to a field of organic light-emitting material technology, and more specifically to an organic light-emitting material containing phosphine, a method for the preparation thereof, and an use thereof in the fields of organic electroluminescence device, chemo-biological detection, bio-imaging, anti-counterfeiting, and the like.

### 2. Description of the Prior Art

Organic electroluminescence materials have great potentials in the fields of panel displays, solid state lighting, and the like, and have been paid much attention by the scientific community and industrial community recently. Organic light-emitting diodes (OLEDs) based on such materials have a lot of advantages of low drive voltage, high response speed, flexibility, wide viewing angle, active luminescence, and the like than conventional displays. The OLEDs will be expected to become next-generation displays. Currently, the OLEDs has been initially marketized and developed rapidly. However, existing organic electroluminescence materials can't meet the requirements of practicality in terms of luminous efficiency, working life, stability, cost, and the like, and it has become a bottleneck of OLED development.

Currently, organic electroluminescence materials, that have been commercialized, are mainly phosphorescent materials of noble metal (e.g., iridium, platinum) coordination complexes. However, noble metals have disadvantages of rare reserves in nature, high price, and non-renewable resource. The large-scale applications of the OLEDs are greatly limited by the disadvantages. Also, the phosphorescent materials have obvious disadvantages in terms of blue light emitting, luminescence stability, and working life, and thus the development of a highly efficient and stable organic light-emitting material has become a necessary tendency of OLED marketization. In order to get a highly efficient and stable organic electroluminescence device, the light-emitting material thereof must meet the following two requirements: (1) the light-emitting material has a high fluorescence quantum efficiency, and a triplet state energy is used as much as possible to improve the external quantum efficiency of the organic electroluminescence device; (2) the transfer efficiency of holes and electrons can be balanced, and the transport balance of carriers is achieved, thereby improving the stability and efficiency of an OLED element. However, for most of organic electroluminescence materials, the hole transport efficiency thereof is much more than electron transport efficiency, since the structure thereof includes a big conjugate plane and some hole transport groups (e.g., carbazole, aniline derivatives). Therefore, the summary “the electron transport efficiency of the organic electroluminescence material is improved to achieve the transport balance of the holes and the electrons” becomes an important development direction in improvement of the organic electroluminescence materials.

Electron-withdrawing groups such as benzimidazole, sulphone, and the like are introduced in the organic electroluminescence material in order to improve the electron transport efficiency of a molecule in the organic electroluminescence material. Such materials in the organic electroluminescence device get good effect, especially in terms of blue light emitting materials. In recent years, organophosphine compounds have been obtained excellent results in terms of electron transport materials. For example, Hui Xu et al. have designed a series of organophosphine compounds containing benzothiophene, that are used as an electron transport material. The minimum triplet state energy of such materials is about 2.9 eV, and such materials are an ideal electron transport material for a blue and white OLED. OLEDs based on such materials have not only a good stability, but also driving voltage as low as 2.4 V and current efficiency over 30 lmW⁻¹. It can be seen that organophosphine functional groups are introduced in a light emitting material, that will not only improve the fluorescence quantum efficiency thereof, but also greatly improve the electron transport capacity of the organic light-emitting material, thereby promoting the transport balance of the holes and the electrons of the organic light-emitting material in the OLED, thus improving the performance of the OLED. Finally, an OLED element having low cost, high efficiency and high stability is obtained. Also, an organic light-emitting material containing phosphine has a wide range of applications in the fields of ion response, oxygen detection, bio-imaging, anti-counterfeiting, and the like.

### SUMMARY OF THE INVENTION

A primary object of the present disclosure is to provide an organic light-emitting material. The organic light-emitting material is a novel organic light-emitting material containing phosphine, and has a high fluorescence quantum efficiency and a good electron-transport property. The organic light-emitting material can be used for preparing a highly efficient and stable OLED element, and can be applied in the fields of chemical detection, bio-imaging, anti-counterfeiting, and the like.

Another object of the present disclosure is to provide a method for preparing an organic light-emitting material. The method has the advantages of simple process, high yield, easy purification of product, and adjustment of the luminous wavelength, the luminous efficiency, and the like of a target product by introducing different functional groups.

A yet another object of the present disclosure is to provide an OLED element, in which the organic light-emitting material is used as an emitting layer and/or an electron transport layer, so that the emitting layer and/or the electron transport layer has a highly efficient and stable performance.

To achieve the above object, the present disclosure provides an organic light-emitting material, and the molecule of the organic light-emitting material is shown as a formula (1):

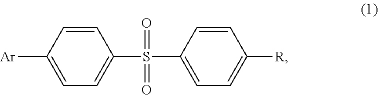

in which Ar is a functional group containing phosphine, R is the same as or different from Ar, and R is an alkyl group, a halogen, an alkoxy group, a nitro group, an amino group, an aldehyde group, a cyano group, an aromatic ring group, or an aromatic heterocyclic group.

In the molecule of the organic light-emitting material, Ar is selected from the following groups:

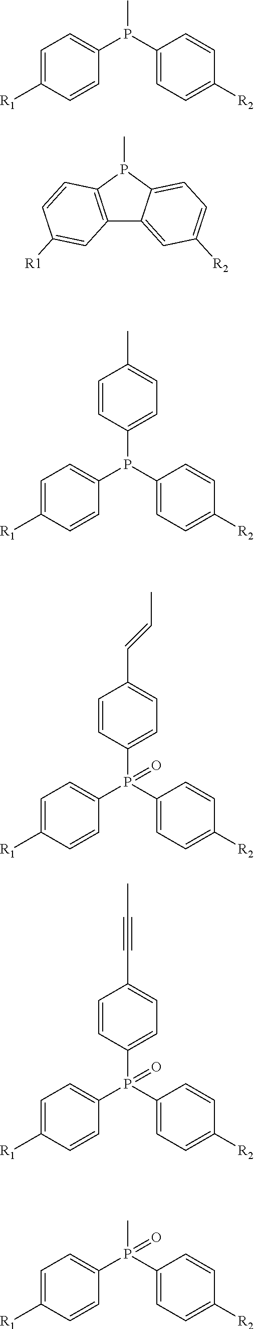

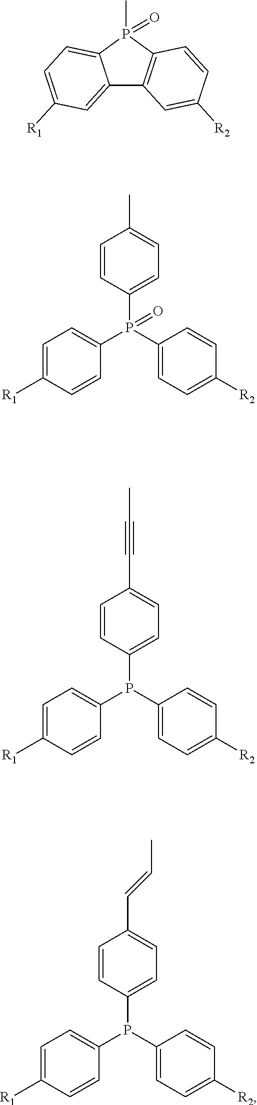

in which R₁ and R₂ are the same or different, and R₁ and R₂ are a hydrogen group, an alkyl group, a halogen, an alkoxy group, a nitro group, an amino group, an aldehyde group, a cyano group, a phenyl group, a naphthyl group, an anthryl group, a carbazolyl group, a diphenylamino group, or a phenothiazinyl group.

In the molecule of the organic light-emitting material, R is selected from the aromatic ring group or the aromatic heterocyclic group as follows:

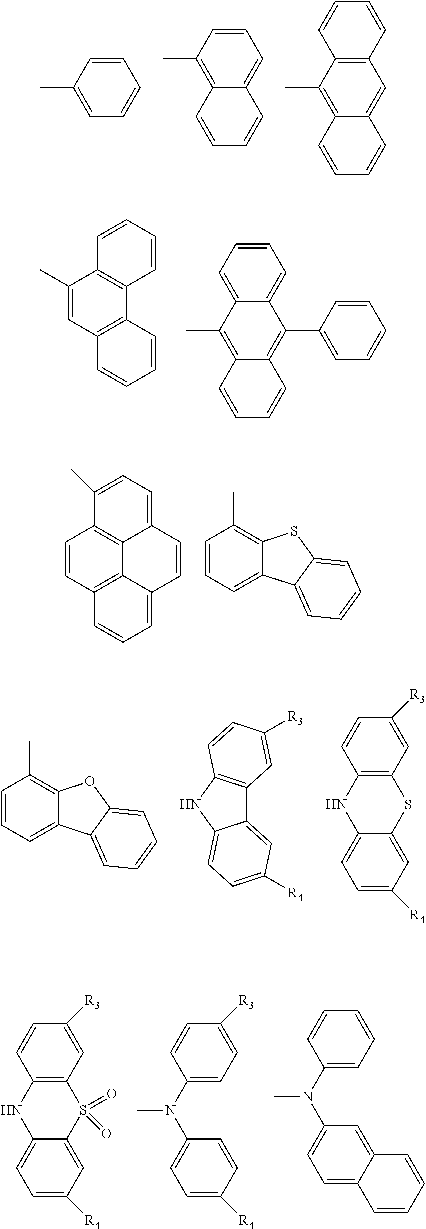

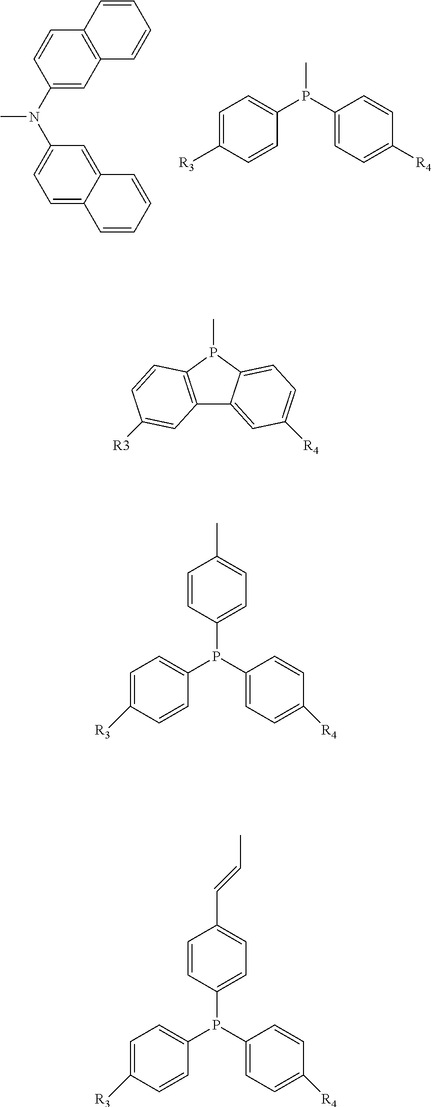

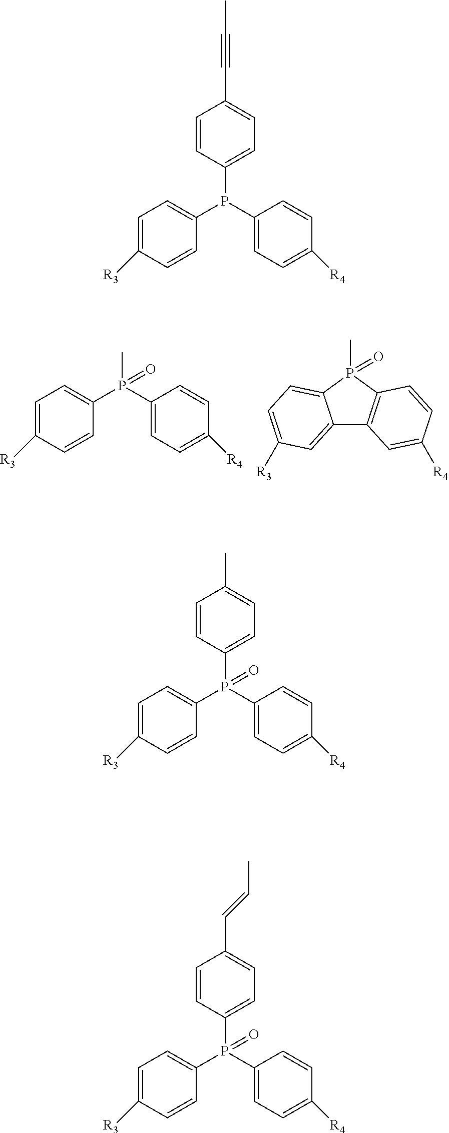

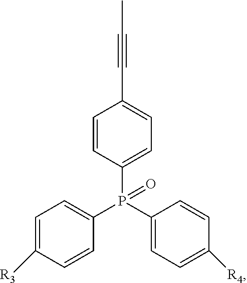

in which R₃ and R₄ are the same or different, and R₃ and R₄ are a hydrogen group, an alkyl group, a halogen, an alkoxy group, a nitro group, an amino group, an aldehyde group, a cyano group, a phenyl group, a naphthyl group, an anthryl group, a carbazolyl group, a diphenylamino group, or a phenothiazinyl group.

The organic light-emitting material is used as a light-emitting material and applied to the preparation of an emitting layer in an OLED element; the organic light-emitting material is used as an electron transport material and applied to the preparation of an electron transport layer in an OLED element; or the organic light-emitting material is used as an electron transport material and a light-emitting material, and respectively applied to the preparations of an emitting layer and an electron transport layer in an OLED element.

The organic light-emitting material is applied in a field of chemo-biological detection, bio-imaging, or anti-counterfeiting.

The present disclosure also provides a method for preparing an organic light-emitting material. The method includes one of the following methods 1-4:

method 1: reacting a diphenylphosphine derivative with a diphenyl sulfone derivative containing iodine on one end or two ends thereof to form a target product;
method 2: reacting 2-(diphenylphosphino)benzylaldehyde and a derivative thereof with a diphenyl sulfone derivative containing a diethyl phosphate group on one end or two ends thereof by a wittig reaction to form a target product;
method 3: reacting halogenated triphenylphosphine and a derivative thereof with a diphenyl sulfone derivative containing an alkynyl group on one end or two ends thereof by a sonogashira coupling reaction to form a target product;
method 4: using the target product formed by the method 1, the method 2, or the method 3 as an intermediate, and oxidizing the intermediate in tetrahydrofuran by hydrogen peroxide to form a target product of phosphine oxide.

The method 1 is implemented by the following process, which includes: providing and dissolving the diphenylphosphine derivative and the diphenyl sulfone derivative containing iodine on one end or two ends thereof into a toluene solution, and then being heated and refluxed under an action of a palladium catalyst to form the target product.

The method 2 is implemented by the following process, which includes: providing and dissolving 2-(diphenylphosphino)benzylaldehyde, the derivative thereof, and the diphenyl sulfone derivative containing the diethyl phosphate group on one end or two ends thereof into a tetrahydrofuran solution, and then being reacted under an action of potassium tert-butoxide by the wittig reaction to form the target product.

The method 3 is implemented by the following process, which includes: providing halogenated triphenylphosphine, the derivative thereof, and the diphenyl sulfone derivative containing the alkynyl group on one end or two ends thereof into a tetrahydrofuran solution, and then being reacted under an action of triethylamine and a palladium catalyst by the sonogashira coupling reaction to form the target product.

The present disclosure provides an OLED element using the above organic light-emitting material. The OLED element includes an emitting layer and an electron transport layer. One of the emitting layer and the electron transport layer includes the organic light-emitting material, or the emitting layer and the electron transport layer include the organic light-emitting material.

The present disclosure has the following beneficial effects. The organic light-emitting material of the present disclosure is a novel organic light-emitting material containing phosphine, and has a high electron-transport property and a high fluorescence quantum efficiency. The organic light-emitting material of the present disclosure can be used as an emitting layer material or an electron transport layer material in the OLED element, and can also be used as the emitting layer material and the electron transport layer material in the OLED element. Thus, an emitting layer and an electron transport layer in the structure of a traditional OLED element can be combined as one layer, thereby the structure and preparation process of the OLED element are simplified. Also, the organic light-emitting material of the present disclosure has a specific response to oxygen, metal ions, and the like, so that the organic light-emitting material can also be applied in the fields of chemo-biological detection, bio-imaging, anti-counterfeiting, and the like. The method for preparing the organic light-emitting material of the present disclosure has the advantages of simple process, high yield, easy purification of product, and adjustment of the luminous wavelength, the luminous efficiency, and the like of the target product by introducing different functional groups. In the OLED element of the present disclosure, the organic light-emitting material is used as an emitting layer and/or an electron transport layer, so that the emitting layer and/or the electron transport layer has a highly efficient and stable performance.

For better understanding of the features and technical contents of the present disclosure, reference will be made to the following detailed description of the present disclosure and the attached drawings. However, the drawings are provided for the purposes of reference and illustration and are not intended to impose undue limitations to the present disclosure.

### BRIEF DESCRIPTION OF THE DRAWINGS

The technical solution, as well as beneficial advantages, of the present disclosure will be apparent from the following detailed description of an embodiment of the present disclosure, with reference to the attached drawings. In the drawings:

FIG. 1 is a picture of comparison of fluorescence emission of solid of organic light-emitting materials prepared by Embodiments 1-4 of the present disclosure; and

FIG. 2 is a picture of comparison of fluorescence emission of organic light-emitting materials prepared by Embodiment 1 of the present disclosure in an oxygen environment and in an oxygen-free environment.

### DETAILED DESCRIPTION OF THE PREFERRED EMBODIMENTS

To further expound the technical solution adopted in the present disclosure and the advantages thereof, a detailed description is given to a preferred embodiment of the present disclosure and the attached drawings.

The present disclosure provides an organic light-emitting material, and the molecule of the organic light-emitting material is shown as a formula (1):

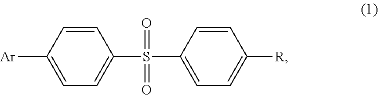

in which Ar is a functional group containing phosphine, R is the same as or different from Ar, and R is an alkyl group, a halogen, an alkoxy group, a nitro group, an amino group, an aldehyde group, a cyano group, an aromatic ring group, or an aromatic heterocyclic group.

Specifically, in the molecule of the organic light-emitting material, Ar is selected from the following groups:

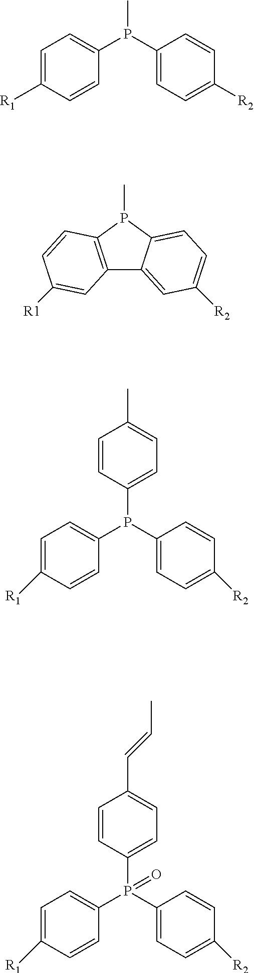

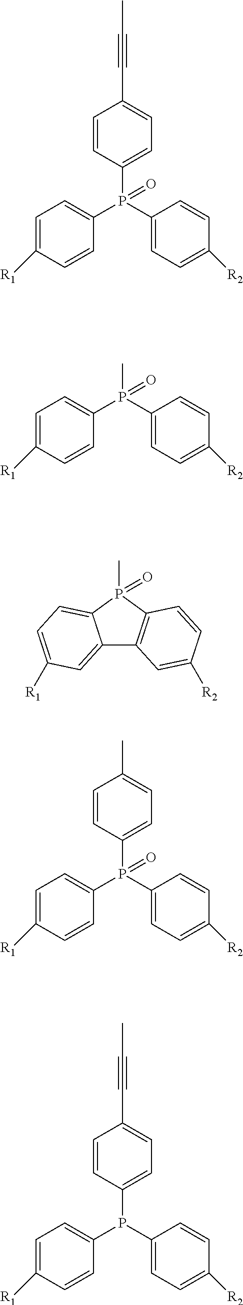

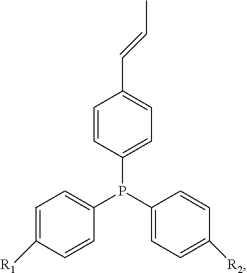

in the structure of the above Ar, R₁ and R₂ can be the same or different, and R₁ and R₂ can be a hydrogen group, an alkyl group, a halogen, an alkoxy group, a nitro group, an amino group, an aldehyde group, a cyano group, a phenyl group, a naphthyl group, an anthryl group, a carbazolyl group, a diphenylamino group, or a phenothiazinyl group.

Specifically, in the molecule of the organic light-emitting material, when R is the aromatic ring group or the aromatic heterocyclic group, R is selected from the following structures:

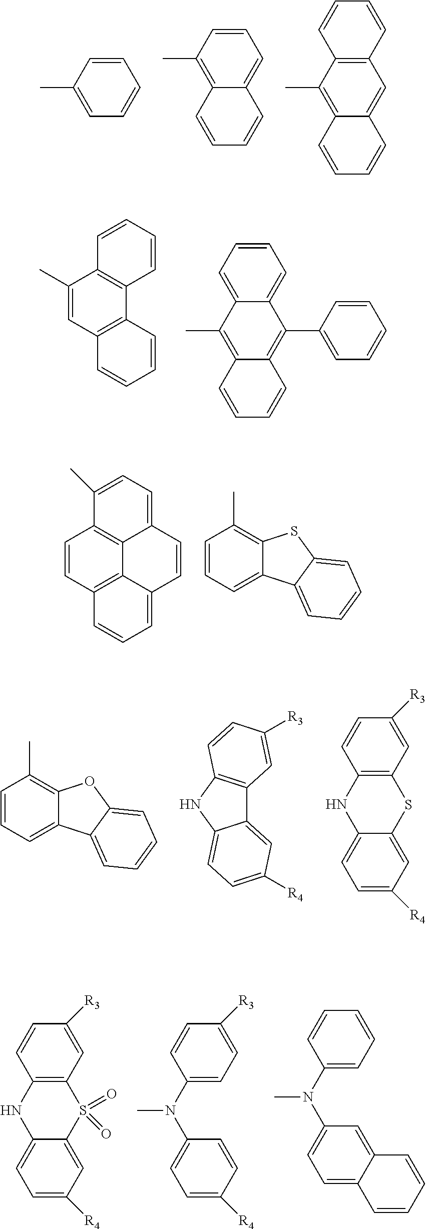

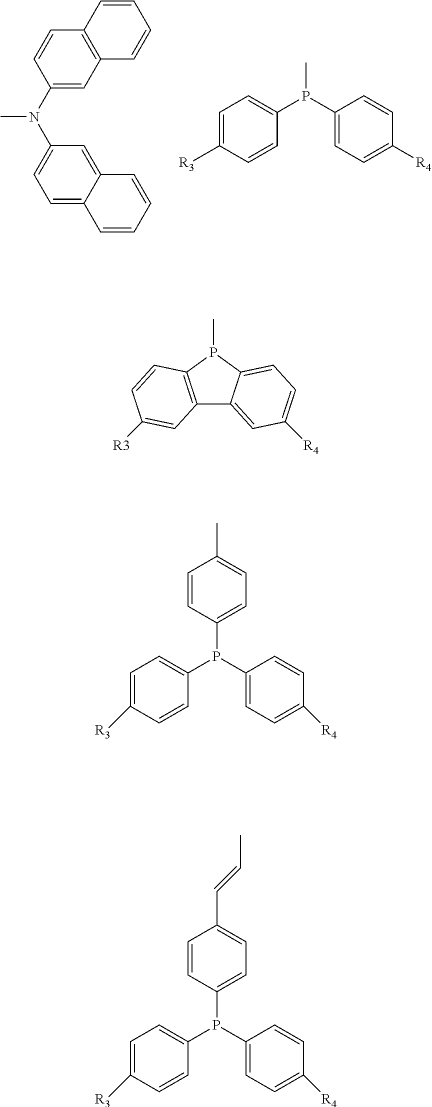

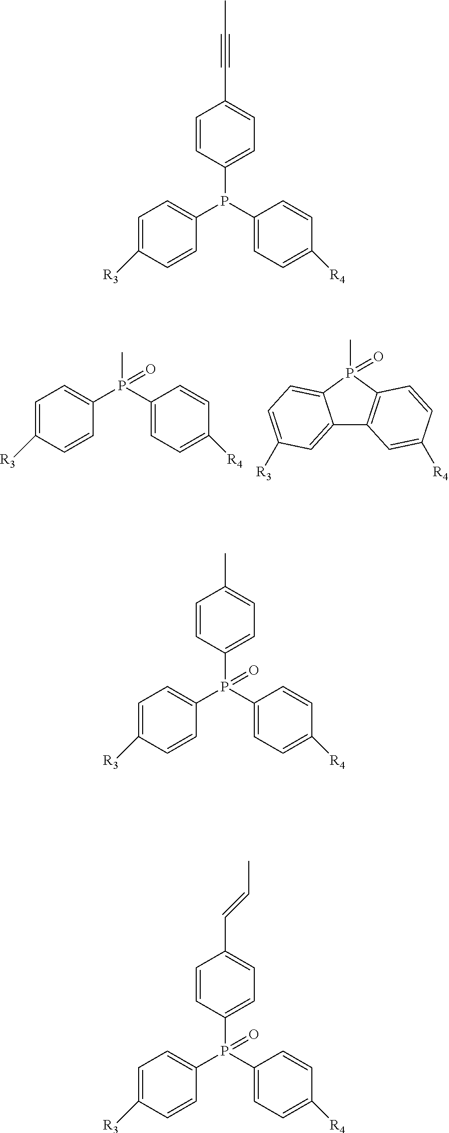

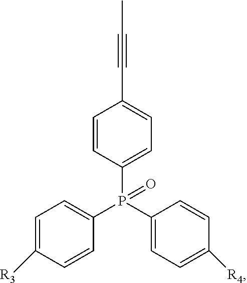

in the structure of the above R, R₃ and R₄ can be the same or different, and R₃ and R₄ can be a hydrogen group, an alkyl group, a halogen, an alkoxy group, a nitro group, an amino group, an aldehyde group, a cyano group, a phenyl group, a naphthyl group, an anthryl group, a carbazolyl group, a diphenylamino group, or a phenothiazinyl group.

The organic light-emitting material of the present disclosure is a novel organic light-emitting material containing phosphine, and has a high electron-transport property and a high fluorescence quantum efficiency. Therefore, the organic light-emitting material of the present disclosure can be used as a light-emitting material and applied to the preparation of an emitting layer in an OLED element. Also, the organic light-emitting material of the present disclosure can be used as an electron transport material and applied to the preparation of an electron transport layer in an OLED element. Also, the organic light-emitting material of the present disclosure can be used as an electron transport material and a light-emitting material, and respectively applied to the preparations of an emitting layer and an electron transport layer in an OLED element.

In addition, the organic light-emitting material of the present disclosure has a specific response to oxygen, metal ions, and the like, and thus the organic light-emitting material can also be applied in the fields of chemo-biological detection, bio-imaging, anti-counterfeiting, and the like.

Base on the above organic light-emitting material, the present disclosure also provides a method for preparing the organic light-emitting material. The method includes one of the following methods 1-4.

In the method 1, a diphenylphosphine derivative is reacted with a diphenyl sulfone derivative containing iodine on one end or two ends thereof to form a target product.

In the method 2, 2-(diphenylphosphino)benzylaldehyde and a derivative thereof are reacted with a diphenyl sulfone derivative containing a diethyl phosphate group on one end or two ends thereof by a wittig reaction to form a target product.

In the method 3, halogenated triphenylphosphine and a derivative thereof are reacted with a diphenyl sulfone derivative containing an alkynyl group on one end or two ends thereof by a sonogashira coupling reaction to form a target product.

In the method 4, the target product formed by the method 1, the method 2, or the method 3 is used as an intermediate, and the intermediate is oxidized in tetrahydrofuran by hydrogen peroxide to form a target product of phosphine oxide.

Specifically, the method 1 is implemented by the following process, which includes: providing and dissolving the diphenylphosphine derivative and the diphenyl sulfone derivative containing iodine on one end or two ends thereof into a toluene solution, and then being heated and refluxed under an action of a palladium catalyst to form the target product. The palladium catalyst is tetrakis(triphenylphosphine)palladium (Pd(PPh₃)₄).

Specifically, the method 2 is implemented by the following process, which includes: providing and dissolving 2-(diphenylphosphino)benzylaldehyde, the derivative thereof, and the diphenyl sulfone derivative containing the diethyl phosphate group on one end or two ends thereof into a tetrahydrofuran solution, and then being reacted under an action of potassium tert-butoxide by the wittig reaction to form the target product.

Specifically, the method 3 is implemented by the following process, which includes: providing halogenated triphenylphosphine, the derivative thereof, and the diphenyl sulfone derivative containing the alkynyl group on one end or two ends thereof into a tetrahydrofuran solution, and then being reacted under an action of triethylamine and a palladium catalyst by the sonogashira coupling reaction to form the target product.

The method for preparing the organic light-emitting material will be further illustrated by the following embodiments 1-4, but the present disclosure is not limited thereto.

### Embodiment 1

(1) 4-fluoro-4′-iodo diphenyl sulfone as an intermediate is synthesized, and the synthetic route thereof is shown as the following equation:

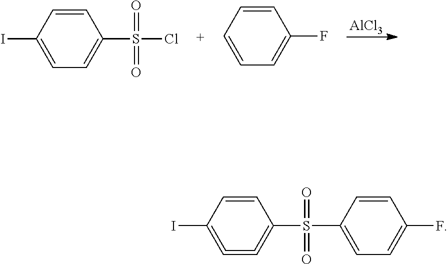

4-iodobenzene sulfonyl chloride (5.00 g, 16.5 mmol) is added in 250 mL of a dried three necked flask, and then fluorobenzene (7.30 g, 76.0 mmol) is added and stirred. Then, anhydrous aluminum chloride (3.31 g, 24.8 mmol) is added, heated to 40-50° C., and reacted for 5-6 hours. 50 mL of dichloromethane is added in the three necked flask after the reaction, and a diluted hydrochloric acid is slowly added, and then is stirred until no precipitation. Then, the reaction mixture is poured in a separating funnel, extracted three times with dichloromethane, and then washed 2-3 times with diluted hydrochloric acid until the water layer turns colorless. The organic layer is dried with anhydrous sodium sulfate, and then is filtrated. The filtrate is spin-dried by a rotary evaporator to obtain 4.80 g of yellowish white solids, and the yield thereof is 80%.

(2) 4-iodo-4′-carbazolyl diphenyl sulfone as an intermediate is synthesized, and the synthetic route thereof is shown as the following equation:

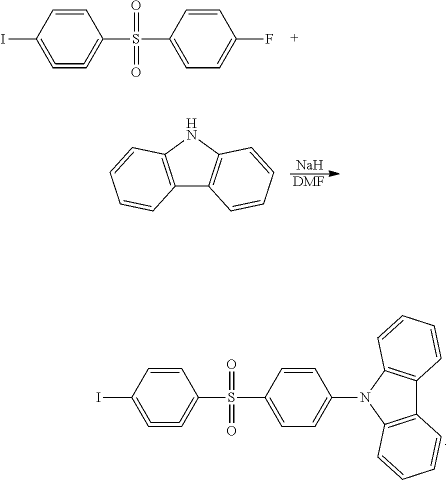

Carbazole (0.48 g, 6.2 mmol) is added in 250 mL of a three necked flask, and then moderate amounts of dimethylformamide (DMF) are added. Then, sodium hydride (0.5 g, 20.9 mmol) is added in an argon environment, and then 4-fluoro-4′-iodo diphenyl sulfone (1.50 g, 4.1 mmol) is added after stirring for 30 minutes. The mixed solution is heated to 110° C., and is reacted for 12 hours, and then the reaction mixture is cooled. Then, dichloromethane and water are added, and extracted three times with dichloromethane, and then washed three times with water. The organic layer is dried with anhydrous sodium sulfate, and is spin-dried by a rotary evaporator, and then is purified by a silica gel column (the eluent thereof is the mixed solution of dichloromethane and n-hexane (volume ratio of 1:2)) to obtain 1.12 g of white solids, and the yield thereof is 52%.

(3) A target product of Embodiment 1 is synthesized, and the synthetic route thereof is shown as the following equation:

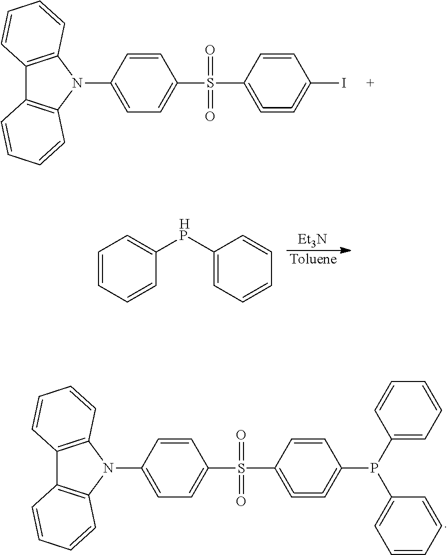

4-iodo-4′-carbazolyl diphenyl sulfone (1.02 g, 2.0 mmol) is dissolved in toluene, and then 2 mL of trimethylamine is added. Then, diphenylphosphine (0.37 g, 2 mmol) is added, and raised the temperature until the solvent is refluxed, and then 0.05 g of tetrakis(triphenylphosphine)palladium as a catalyst is added. The reaction mixture is cooled after stirring-refluxing for 36 hours, and then is filtrated. The filtrate is dried by a rotary evaporator, and then is purified by a silica gel column (the eluent thereof is the mixed solution of dichloromethane and n-hexane (volume ratio of 3:1)) to obtain 0.75 g of a pure product, and the yield thereof is 66%.

### Embodiment 2

The synthetic route of A target product of Embodiment 2 is shown as the following equation:

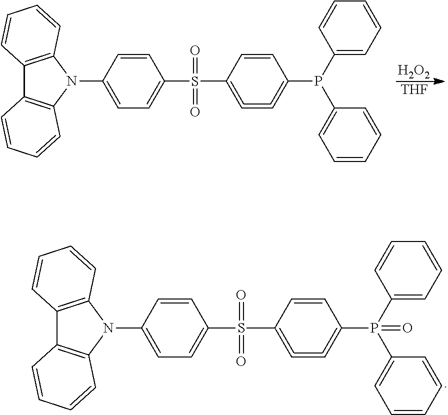

The target product of Embodiment 1 (0.25 g, 0.44 mmol) is added in a round-bottom flask, and 20 ml of tetrahydrofuran is added, and then 6 mL of hydrogen peroxide solution (30%) is added. 50 ml of dichloromethane and 50 ml of water are added in the reaction mixture after stirring for 5 hours, and then separated. The dichloromethane layer is spin-dried by a rotary evaporator to obtain a white powder. The white powder is recrystallized with dichloromethane/n-hexane to obtain 0.20 g of white solids, and the yield thereof is 77%.

### Embodiment 3

(1) 4-iodo-4′-phenothiazinyl diphenyl sulfone as an intermediate is synthesized, and the synthetic route thereof is shown as the following equation:

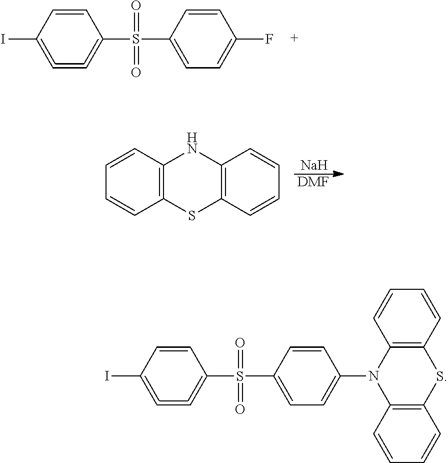

According to the step (2) of the above Embodiment 1, carbazole is replaced by phenothiazine to synthesize 4-iodo-4′-phenothiazinyl diphenyl sulfone (yield: 55%).

(2) A target product of Embodiment 3 is synthesized, and the synthetic route thereof is shown as the following equation:

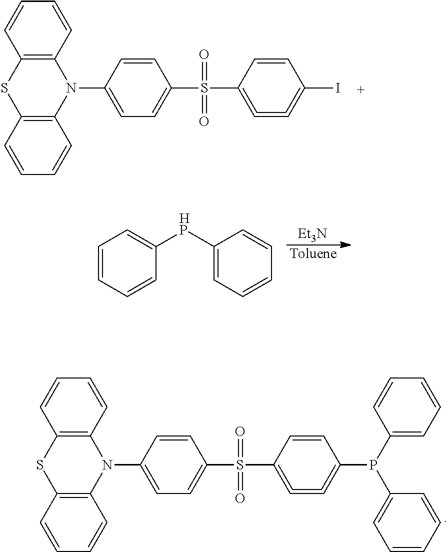

According to the step (3) of the above Embodiment 1, carbazole is replaced by phenothiazine to synthesize 4-iodo-4′-phenothiazinyl diphenyl sulfone (yield: 60%).

### Embodiment 4

(1) 4-methyl-4′-iodo diphenyl sulfone as an intermediate is synthesized, and the synthetic route thereof is shown as the following equation:

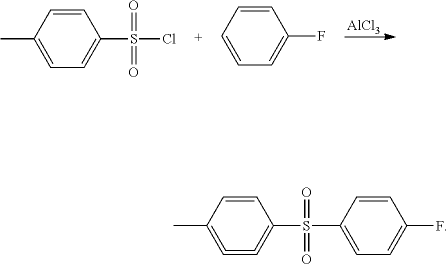

According to the step (1) of the above Embodiment 1, p-iodobenzene sulfonyl chloride is replaced by p-toluenesulfonyl chloride to synthesize 4-methyl-4′-fluoro diphenyl sulfone (yield: 72%).

(2) 4-methyl-4′-carbazolyl diphenyl sulfone as an intermediate is synthesized, and the synthetic route thereof is shown as the following equation:

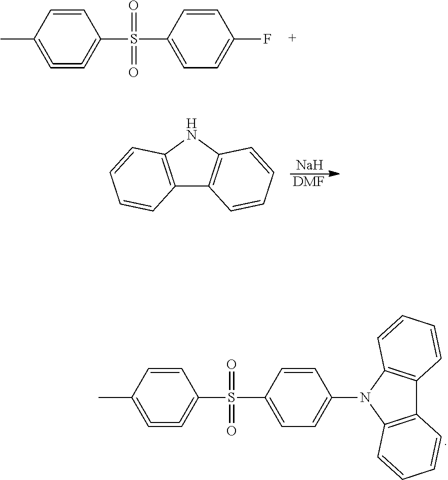

According to the step (2) of the above Embodiment 1, 4-fluoro-4′-iodo diphenyl sulfone is replaced by 4-methyl-4′-iodo diphenyl sulfone to synthesize 4-methyl-4′-carbazolyl diphenyl sulfone (yield: 67%).

(3) 4-bromomethylene-4′-carbazolyl diphenyl sulfone as an intermediate is synthesized, and the synthetic route thereof is shown as the following equation:

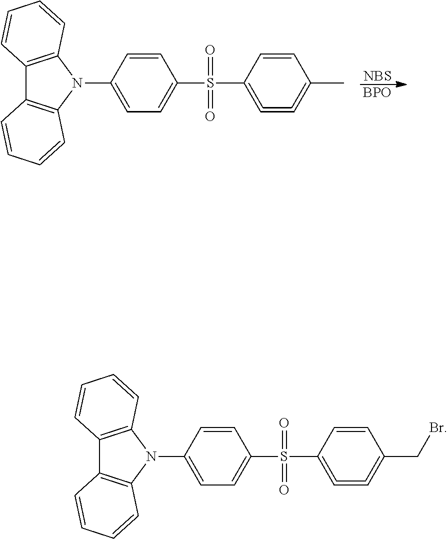

4-methyl-4′-carbazolyl diphenyl sulfone (3.10 g, 7.8 mmol) is dissolved in 1,2-dichloroethane. Then, N-bromosuccinimide (NBS) (2.84 g, 16.0 mmol) is added, and raised the temperature until the solvent is refluxed, and then benzoperoxide (BPO) as an initiator is added. The reaction mixture is cooled after stirring-refluxing for 12 hours, and then 50 ml of dichloromethane and 50 ml of water are added. Then, anhydrous sodium sulfate is added after the organic phase is washed three times, and then is dried and filtrated. The filtrate is dried by a rotary evaporator to obtain 2.25 g of a product, and the yield thereof is 61%.

(4) 4-diethylphosphate methylene-4′-carbazolyl diphenyl sulfone as an intermediate is synthesized, and the synthetic route thereof is shown as the following equation:

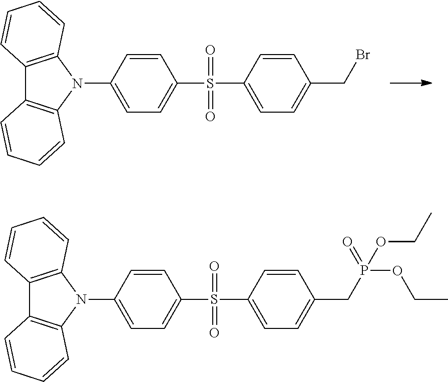 [SMILES: O=S(=O)(c1ccc(CBr)cc1)c1ccc(-n2c3ccccc3c3ccccc32)cc1 ; CCOP(=O)(Cc1ccc(S(=O)(=O)c2ccc(-n3c4ccccc4c4ccccc43)cc2)cc1)OCC]

4-bromomethylene-4′-carbazolyl diphenyl sulfone (1.00 g, 2.1 mmol) is dissolved in 30 ml of triethyl phosphite, and raised the temperature until the solvent is refluxed. The reaction mixture is cooled after stirring-refluxing for 12 hours, and then is pressure-distilled to obtain 0.72 g of dark brown solids, and the yield thereof is 68%.

(5) A target product of Embodiment 4 is synthesized, and the synthetic route thereof is shown as the following equation:

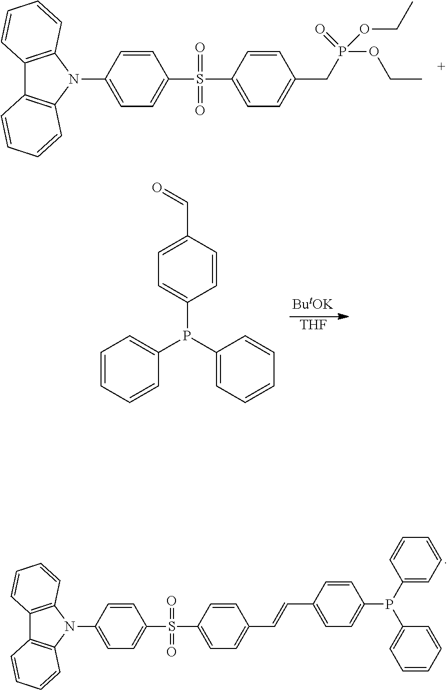 [SMILES: CCOP(=O)(Cc1ccc(S(=O)(=O)c2ccc(-n3c4ccccc4c4ccccc43)cc2)cc1)OCC ; O=Cc1ccc(P(c2ccccc2)c2ccccc2)cc1 ; O=S(=O)(c1ccc(/C=C/c2ccc(P(c3ccccc3)c3ccccc3)cc2)cc1)c1ccc(-n2c3ccccc3c3ccccc32)cc1 ; "THF"]

4-diethylphosphate methylene-4′-carbazolyl diphenyl sulfone (0.20 g, 0.38 mmol) and 4-(diphenylphosphino)benzylaldehyde (0.29 g, 1.0 mmol) are dissolved in tetrahydrofuran, and then potassium tert-butoxide (0.11 g, 1.0 mmol) is added. 50 ml of dichloromethane and 50 ml of water are added in the reaction mixture after stirring for 5 hours, and then separated. The organic phase is separated, and spin-dried by a rotary evaporator. The crude product thereof is recrystallized with dichloromethane/n-hexane to obtain 0.18 g of white solids, and the yield thereof is 68%.

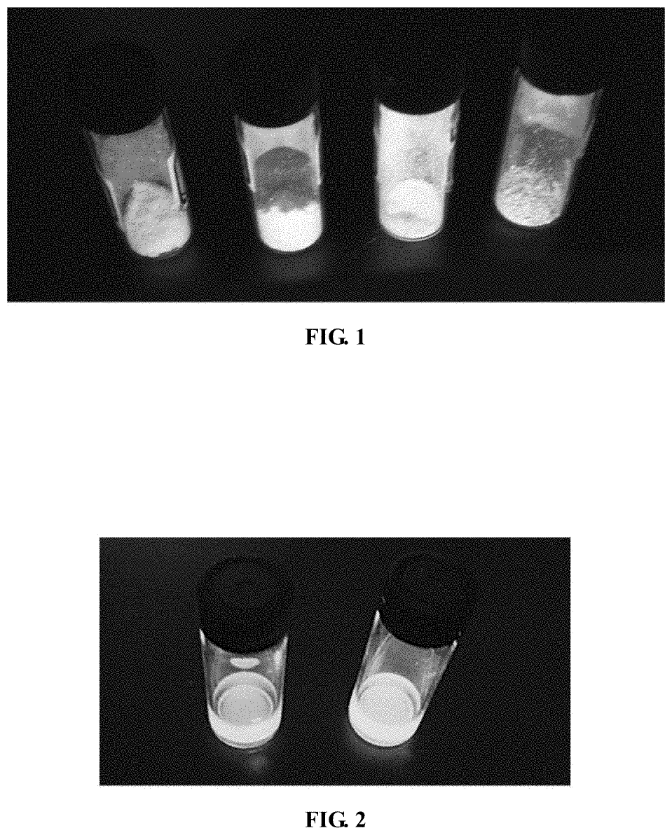

For better illustrating of the performance of the organic light-emitting material of the present disclosure, the performance of target products synthesized by the Embodiments 1-4 is tested. That focuses on the maximum fluorescence emission wavelength, luminescent lifetime, and CIE coordinate of luminescence of solid of the target products of the Embodiments 1-4 in solution and solid, and the results thereof are shown as Table 1. FIG. 1 is a picture of fluorescence emission of solid of the target products synthesized by the Embodiments 1-4. Samples (from left to right) in FIG. 1 are the target products synthesized by the Embodiments 1-4, respectively. It can be seen with eyes that the solids of the target products synthesized by the Embodiments 1-4 are capable of emitting different fluorescence wavelengths in a dark environment.

TABLE 1

| | fluorescence | | fluorescence | | |
|---|---|---|---|---|---|
| | emission | luminescent | emission | luminescent | |
| | wavelength of | lifetime of | wavelength | lifetime | CIE coordinate |
| | solution/ | solution | of solid/ | of solid | of luminescence |
| compound | nm | τ/s | nm | τ/s | of solid |
| Embodiment 1 | 425 | 8.31 × 10⁻⁹ | 485 | 4.02 × 10⁻⁷(61.5%) | (0.2279, 0.2878) |
| | | | | 8.58 × 10⁻⁵(38.5%) | |
| Embodiment 2 | 449 | 9.91 × 10⁻⁹ | 430 | 7.76 × 10⁻⁹(79.9%) | (0.1653, 0.1161) |
| | | | | 3.70 × 10⁻⁸(20.1%) | |
| Embodiment 3 | 597 | 8.17 × 10⁻⁹ | 490 | 4.34 × 10⁻³(71.5%) | (0.2483, 0.3947) |
| | | | | 3.78 × 10⁻⁵(28.5%) | |
| Embodiment 4 | 473 | 9.39 × 10⁻⁹ | 467 | 2.72 × 10⁻⁹(79.2%) | (0.2161, 0.2660) |
| | | | | 1.26 × 10⁻⁸(20.8%) | |

The emission spectrum and fluorescence lifetime of solution and solid are measured by a Horiba JY FluoroLog-3 fluorescence spectrometer. The CIE color coordinate of luminescence of solid is measured by a Photo Research Spectra Scan PR655 colorimeter.

In addition, FIG. 2 is a picture of fluorescence emission of the target products synthesized by the Embodiment 1 in an oxygen environment and in an oxygen-free environment. In FIG. 2, samples on the left and right are the target product in the oxygen-free environment and the target product in the oxygen environment, respectively. It can be known that the organic light-emitting material of the present disclosure has a specific response to oxygen and the like, and thus the organic light-emitting material of the present disclosure is also applied in the fields of chemo-biological detection, bio-imaging, anti-counterfeiting, and the like.

Also, the present disclosure provides an OLED element using the above organic light-emitting material. The OLED element includes an emitting layer and an electron transport layer. One of the emitting layer and the electron transport layer includes the organic light-emitting material, or the emitting layer and the electron transport layer include the organic light-emitting material.

As mentioned above, the organic light-emitting material of the present disclosure is a novel organic light-emitting material containing phosphine, and has a high electron-transport property and a high fluorescence quantum efficiency. The organic light-emitting material of the present disclosure can be used as an emitting layer material or an electron transport layer material in the OLED element, and can also be used as the emitting layer material and the electron transport layer material in the OLED element. Thus, an emitting layer and an electron transport layer in the structure of a traditional OLED element can be combined as one layer, thereby the structure and preparation process of the OLED element are simplified. Also, the organic light-emitting material of the present disclosure has a specific response to oxygen, metal ions, and the like, so that the organic light-emitting material can also be applied in the fields of chemo-biological detection, bio-imaging, anti-counterfeiting, and the like. The method for preparing the organic light-emitting material of the present disclosure has the advantages of simple process, high yield, easy purification of product, and adjustment of the luminous wavelength, the luminous efficiency, and the like of the target product by introducing different functional groups. In the OLED element of the present disclosure, the organic light-emitting material is used as an emitting layer and/or an electron transport layer, so that the emitting layer and/or the electron transport layer has a highly efficient and stable performance.

Based on the description given above, those having ordinary skills of the art may easily contemplate various changes and modifications of the technical solution and technical ideas of the present disclosure and all these changes and modifications are considered within the protection scope of right for the present disclosure.

What is claimed is:

1. An organic light-emitting material, wherein a molecule of the organic light-emitting material is shown as a formula (1): 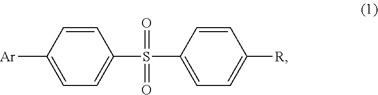
wherein Ar is a functional group containing phosphine, R is the same as or different from Ar, and R is an alkyl group, a halogen, an alkoxy group, a nitro group, an amino group, an aldehyde group, a cyano group, an aromatic ring group, or an aromatic heterocyclic group.

2. The organic light-emitting material of claim 1, wherein in a molecule of the organic light-emitting material, Ar is selected from the following groups: 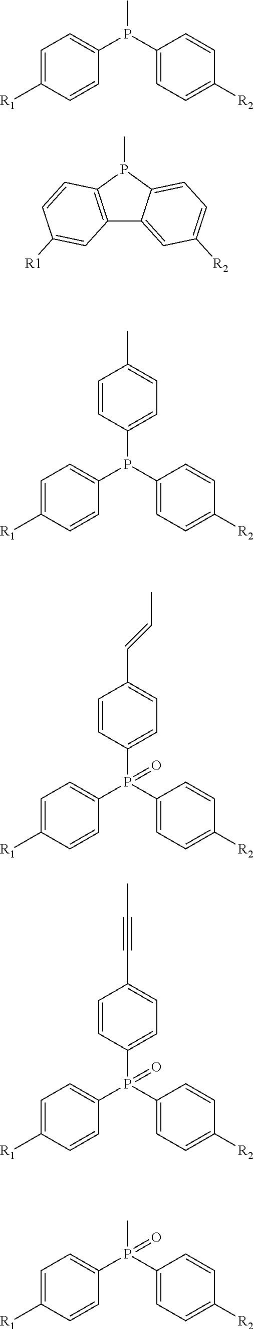 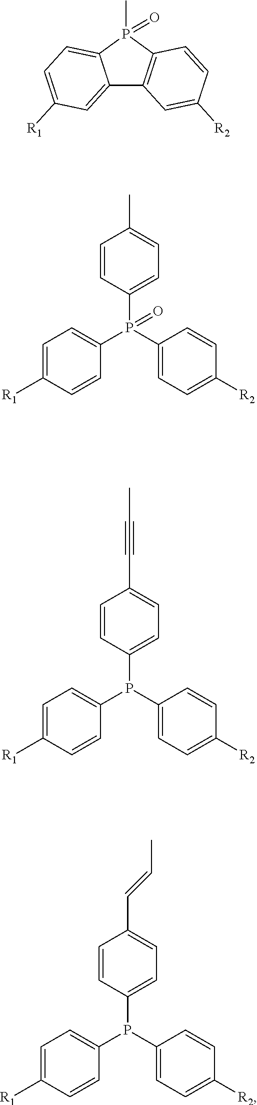
wherein R₁ and R₂ are the same or different, and R₁ and R₂ are a hydrogen group, an alkyl group, a halogen, an alkoxy group, a nitro group, an amino group, an aldehyde group, a cyano group, a phenyl group, a naphthyl group, an anthryl group, a carbazolyl group, a diphenylamino group, or a phenothiazinyl group.

3. The organic light-emitting material of claim 1, wherein in a molecule of the organic light-emitting material, R is selected from the aromatic ring group or the aromatic heterocyclic group as follows: 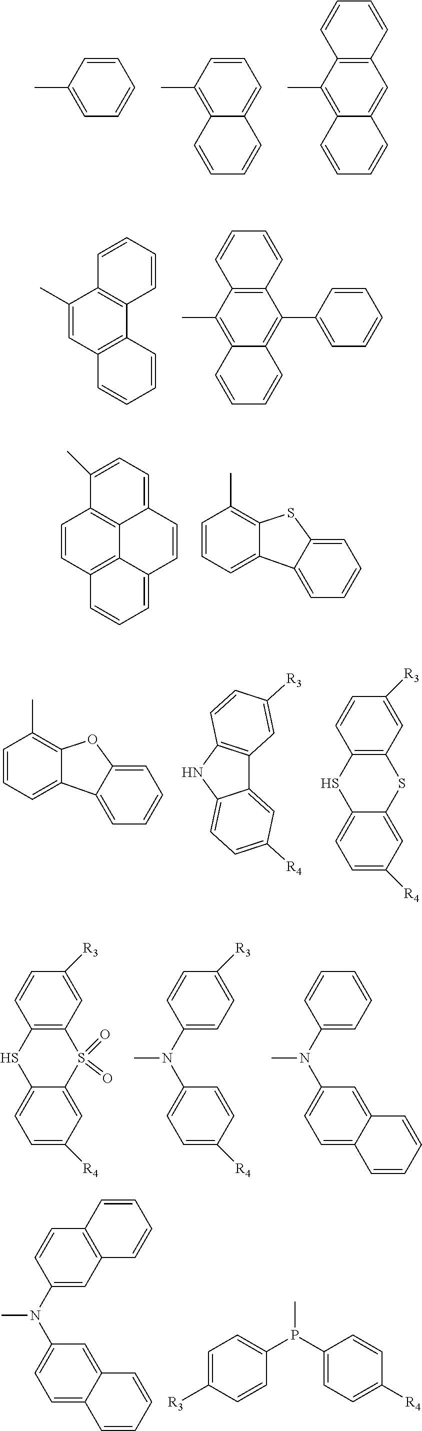 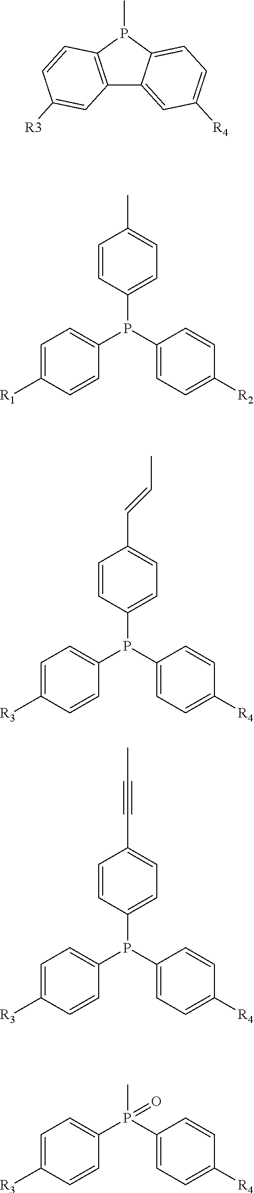 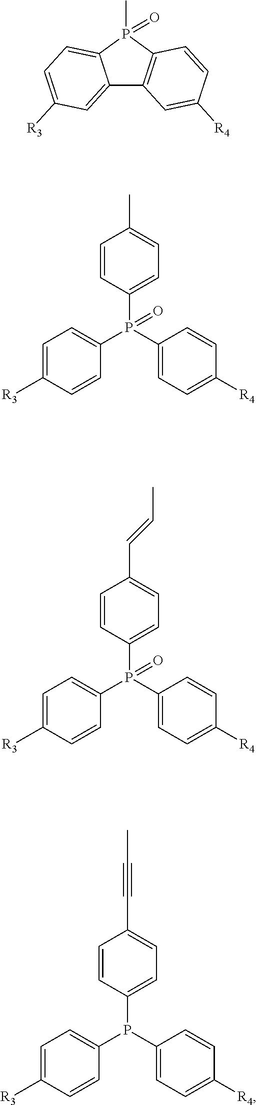
wherein R₃ and R₄ are the same or different, and R₃ and R₄ are a hydrogen group, an alkyl group, a halogen, an alkoxy group, a nitro group, an amino group, an aldehyde group, a cyano group, a phenyl group, a naphthyl group, an anthryl group, a carbazolyl group, a diphenylamino group, or a phenothiazinyl group.

4. The organic light-emitting material of claim 1, wherein the organic light-emitting material is used as a light-emitting material and applied to a preparation of an emitting layer in an OLED (organic light-emitting diode) element; the organic light-emitting material is used as an electron transport material and applied to a preparation of an electron transport layer in an OLED element; or the organic light-emitting material is used as an electron transport material and a light-emitting material, and respectively applied to preparations of an emitting layer and an electron transport layer in an OLED element.

5. The organic light-emitting material of claim 1, wherein the organic light-emitting material is applied in a field of chemo-biological detection, bio-imaging, or anti-counterfeiting.

6. A method for preparing the organic light-emitting material of claim 1, comprising one of the following methods 1-4:
method 1: reacting a diphenylphosphine derivative with a diphenyl sulfone derivative containing iodine on one end or two ends thereof to form a target product;
method 2: reacting 2-(diphenylphosphino)benzylaldehyde and a derivative thereof with a diphenyl sulfone derivative containing a diethyl phosphate group on one end or two ends thereof by a wittig reaction to form a target product;
method 3: reacting halogenated triphenylphosphine and a derivative thereof with a diphenyl sulfone derivative containing an alkynyl group on one end or two ends thereof by a sonogashira coupling reaction to form a target product;
method 4: using the target product formed by the method 1, the method 2, or the method 3 as an intermediate, and oxidizing the intermediate in tetrahydrofuran by hydrogen peroxide to form a target product of phosphine oxide.

7. The method for preparing the organic light-emitting material of claim 6, wherein the method 1 is implemented by the following process, which comprises: providing and dissolving the diphenylphosphine derivative and the diphenyl sulfone derivative containing iodine on one end or two ends thereof into a toluene solution, and then being heated and refluxed under an action of a palladium catalyst to form the target product.

8. The method for preparing the organic light-emitting material of claim 6, wherein the method 2 is implemented by the following process, which comprises: providing and dissolving 2-(diphenylphosphino)benzylaldehyde, the derivative thereof, and the diphenyl sulfone derivative containing the diethyl phosphate group on one end or two ends thereof into a tetrahydrofuran solution, and then being reacted under an action of potassium tert-butoxide by the wittig reaction to form the target product.

9. The method for preparing the organic light-emitting material of claim 6, wherein the method 3 is implemented by the following process, which comprises: providing halogenated triphenylphosphine, the derivative thereof, and the diphenyl sulfone derivative containing the alkynyl group on one end or two ends thereof into a tetrahydrofuran solution, and then being reacted under an action of triethylamine and a palladium catalyst by the sonogashira coupling reaction to form the target product.

10. An OLED (organic light-emitting diode) element using the organic light-emitting material of claim 1, wherein the OLED element comprises an emitting layer and an electron transport layer, and one of the emitting layer and the electron transport layer comprises the organic light-emitting material; or the emitting layer and the electron transport layer comprise the organic light-emitting material.
